(19) United States
(12) Patent Application Publication
(10) Pub. No.: US 2011/0278536 A1
(43) Pub. Date: Nov. 17, 2011

(54) LIGHT EMITTING MATERIAL

(75) Inventors: Brian J. Walker, Somerville, MA (US); Moungi G. Bawendi, Cambridge, MA (US); Vladimir Bulovic, Lexington, MA (US)

(73) Assignee: Massachusetts Institute of Technology, Cambridge, MA (US)

(21) Appl. No.: 12/781,557

(22) Filed: May 17, 2010

(51) Int. Cl. H01L 33/04; H01L 21/20

(52) U.S. Cl. 257/13; 438/479; 257/E33.008; 257/E21.09

(57) ABSTRACT

A film can include a plurality of semiconductor nanocrystals and a J-aggregating material in solution. The film can exhibit 90% energy transfer efficiency from the J-aggregating material to the plurality of semiconductor nanocrystals. The film can exhibit photoluminescence that is enhanced at least 2.5 times over an equivalent film including the plurality of semiconductor nanocrystals alone when excited at 465 nm. The film can be contacted onto a substrate by spin casting.

### TECHNICAL FIELD

The present invention relates to a light emitting material.

### BACKGROUND

Light-emitting devices can be used, for example, in displays (e.g., flat-panel displays), screens (e.g., computer screens), and other items that require illumination. Accordingly, the brightness of the light-emitting device is one important feature of the device. Also, low operating voltages and high efficiencies can improve the viability of producing emissive devices.

Light-emitting devices can release photons in response to excitation of an active component of the device. Emission can be stimulated by applying a voltage across the active component (e.g., an electroluminescent component) of the device. The electroluminescent component can be a polymer, such as a conjugated organic polymer or a polymer containing electroluminescent moieties or layers of organic molecules. Typically, the emission can occur by radiative recombination of an excited charge between layers of a device. The emitted light has an emission profile that includes a maximum emission wavelength, and an emission intensity, measured in luminance (candelas/square meter (cd/m²) or power flux (W/m²)). The emission profile, and other physical characteristics of the device, can be altered by the electronic structure (e.g., energy gaps) of the material. For example, the brightness, range of color, efficiency, operating voltage, and operating half-lives of light-emitting devices can vary based on the structure of the device.

### SUMMARY

In one embodiment, a film can include a plurality of semiconductor nanocrystals and a J-aggregating material, the plurality of semiconductor nanocrystals and the J-aggregating material can be arranged on a surface and to transfer energy. The energy transfer efficiency from the J-aggregating material to the plurality of semiconductor nanocrystals can be greater than 80%. In another embodiment, the energy transfer efficiency from the J-aggregating material to the plurality of semiconductor nanocrystals can be 90%.

In another embodiment, the film can include a plurality of semiconductor nanocrystals including a cationic surface ligand. The photoluminescence of the film can be enhanced at least 2.5 times over an equivalent film including the plurality of semiconductor nanocrystals alone when excited at 465 nm. The illumination of the film at 457 nm can result in enhanced emission at 620 nm and quenched emission at 472 nm.

In another embodiment, a light emitting device can include a film containing a plurality of semiconductor nanocrystal and a J-aggregating material, the plurality of semiconductor nanocrystal and J-aggregating material can be arranged on a substrate and to transfer energy. The energy transfer efficiency from the J-aggregating material to the plurality of semiconductor nanocrystals can be greater than 80%. In another embodiment, the energy transfer efficiency from the J-aggregating material to the plurality of semiconductor nanocrystals can be 90%. The photoluminescence of the device can be enhanced at least 2.5 times over an equivalent film including the plurality of semiconductor nanocrystals alone when excited at 465 nm. The illumination of the device at 457 nm can result in enhanced emission at 620 nm and quenched emission at 472 nm. The substrate can include glass, plastic, or quartz.

In another embodiment, a method of making a film can include contacting a solution containing a plurality of semiconductor nanocrystals and a J-aggregating material with a substrate, and arranging a plurality of semiconductor nanocrystals and a J-aggregating material on the substrate and to transfer energy. Producing a plurality of semiconductor nanocrystals can include adding a cationic surface ligand. In another embodiment, the plurality of semiconductor nanocrystals can be suspended in a fluorinated solvent, such as fluorinated ethanol or fluorinated ethane. In some embodiments, contacting the solution containing the plurality of semiconductor nanocrystals and the J-aggregating material with a substrate can include spin casting. The substrate can include glass, plastic, or quartz.

Other features, objects, and advantages will be apparent from the description and drawings, and from the claims.

### DESCRIPTION OF DRAWINGS

FIG. 1A shows a schematic of electrostatic conjugation.

FIG. 1B shows a transition electron micrograph.

FIG. 1C shows absorption spectra.

FIG. 1D shows photoluminescence excitation spectra.

FIG. 2 shows photographs of semiconductor nanocrystal and NC/J-aggregate thin films.

FIG. 3 shows photoluminescence spectra.

FIG. 4 shows tapping-mode atomic force micrographs.

FIG. 5 shows a linear fit.

FIG. 6 shows the scatter graphs.

FIG. 7 shows fluorescence micrographs.

FIG. 8 shows photographs using 360 nm broad band illumination and a long pass filter 485 nm to remove excitation light.

### DETAILED DESCRIPTION

In general, a light emitting material can be capable of absorbing light at a first wavelength and subsequently emitting light at a second wavelength. In some materials, the absorption and emission occur on different moieties. A first moiety can absorb light at an absorption wavelength, thereby achieving a higher energy excited state. The excited moiety can transfer energy (e.g. by Forster resonance energy transfer or FRET, or another energy-transfer mechanism) to a second moiety. The second moiety thus achieves an excited state capable of emitting light at an emission wavelength. In many cases, the first moiety can achieve its excited state by other means than absorption of light, such as electrical excitation or energy transfer from other excited species. The efficiency of energy transfer can depend on (among other factors) the distance between the first and second moieties. See, for example, U.S. Patent Application No. 60/935,530, filed Aug. 17, 2007, which is incorporated by reference in its entirety.

The moieties can be associated with one another by a covalent or non-covalent interaction. Non-covalent interactions include but are not limited to hydrogen bonding, electrostatic attraction, hydrophobic interactions, and aromatic stacking interactions. In some cases, electrostatic interactions can be favorable, for example, when one moiety bears (or is capable of bearing) a charge.

One example of a light-emitting moiety is a J-aggregating material (for example, a cyanine dye). The J-aggregating material can have individual dipoles that can couple together to produce a coherent quantum mechanical state (a j-band state). These j-band states are known to absorb and emit light with a very narrow full width half max (FWHM) of 15 nm or less, sometimes as small as 5 nm. J-aggregates are generally charged; the charged nature of the J-aggregated can be exploited to form electrostatically associated conjugates with other materials capable of undergoing energy transfer with the J-aggregate.

The semiconductor nanocrystals can have a broad absorption band with an intense, narrow band emission. The peak wavelength of emission can be tuned from throughout the visible and infrared regions, depending on the size, shape, composition, and structural configuration of the nanocrystals. The nanocrystals can be prepared with an outer surface having desired chemical characteristics (such as a desired solubility). Light emission by nanocrystals can be stable for long periods of time.

When a nanocrystal achieves an excited state (or in other words, an exciton is located on the nanocrystal), emission can occur at an emission wavelength. The emission has a frequency that corresponds to the band gap of the quantum confined semiconductor material. The band gap is a function of the size of the nanocrystal. Nanocrystals having small diameters can have properties intermediate between molecular and bulk forms of matter. For example, nanocrystals based on semiconductor materials having small diameters can exhibit quantum confinement of both the electron and hole in all three dimensions, which leads to an increase in the effective band gap of the material with decreasing crystallite size. Consequently, both the optical absorption and emission of nanocrystals shift to the blue, or to higher energies, as the size of the crystallites decreases.

The emission from the nanocrystal can be a narrow Gaussian emission band that can be tuned through the complete wavelength range of the ultraviolet, visible, or infrared regions of the spectrum by varying the size of the nanocrystal, the composition of the nanocrystal, or both. For example, CdSe can be tuned in the visible region and InAs can be tuned in the infrared region. The narrow size distribution of a population of nanocrystals can result in emission of light in a narrow spectral range. The population can be monodisperse and can exhibit less than a 15% rms deviation in diameter of the nanocrystals, preferably less than 10%, more preferably less than 5%. Spectral emissions in a narrow range of no greater than about 75 nm, preferably 60 nm, more preferably 40 nm, and most preferably 30 nm full width at half max (FWHM) for nanocrystals that emit in the visible can be observed. IR-emitting nanocrystals can have a FWHM of no greater than 150 nm, or no greater than 100 nm. Expressed in terms of the energy of the emission, the emission can have a FWHM of no greater than 0.05 eV, or no greater than 0.03 eV. The breadth of the emission decreases as the dispersity of nanocrystal diameters decreases. Semiconductor nanocrystals can have high emission quantum efficiencies such as greater than 10%, 20%, 30%, 40%, 50%, 60%, 70%, or 80%.

The semiconductor forming the nanocrystals can include a Group II-VI compound, a Group II-V compound, a Group III-VI compound, a Group III-V compound, a Group IV-VI compound, a Group I-III-VI compound, a Group II-IV-VI compound, or a Group II-IV-V compound, for example, ZnO, ZnS, ZnSe, ZnTe, CdO, CdS, CdSe, CdTe, MgO, MgS, MgSe, MgTe, HgO, HgS, HgSe, HgTe, AN, AlP, AlAs, AlSb, GaN, GaP, GaAs, GaSb, InN, InP, InAs, InSb, TlN, TlP, TlAs, TlSb, TlSb, PbS, PbSe, PbTe, or mixtures thereof.

Methods of preparing monodisperse semiconductor nanocrystals include pyrolysis of organometallic reagents, such as dimethyl cadmium, injected into a hot, coordinating solvent. This permits discrete nucleation and results in the controlled growth of macroscopic quantities of nanocrystals. Preparation and manipulation of nanocrystals are described, for example, in U.S. Pat. Nos. 6,322,901 and 6,576,291, and U.S. Patent Application No. 60/550,314, each of which is incorporated by reference in its entirety. The method of manufacturing a nanocrystal is a colloidal growth process. Colloidal growth occurs by rapidly injecting an M donor and an X donor into a hot coordinating solvent. The injection produces a nucleus that can be grown in a controlled manner to form a nanocrystal. The reaction mixture can be gently heated to grow and anneal the nanocrystal. Both the average size and the size distribution of the nanocrystals in a sample are dependent on the growth temperature. The growth temperature necessary to maintain steady growth increases with increasing average crystal size. The nanocrystal is a member of a population of nanocrystals. As a result of the discrete nucleation and controlled growth, the population of nanocrystals obtained has a narrow, monodisperse distribution of diameters. The monodisperse distribution of diameters can also be referred to as a size. The process of controlled growth and annealing of the nanocrystals in the coordinating solvent that follows nucleation can also result in uniform surface derivatization and regular core structures. As the size distribution sharpens, the temperature can be raised to maintain steady growth. By adding more M donor or X donor, the growth period can be shortened.

The M donor can be an inorganic compound, an organometallic compound, or elemental metal. M is cadmium, zinc, magnesium, mercury, aluminum, gallium, indium or thallium. The X donor is a compound capable of reacting with the M donor to form a material with the general formula MX. Typically, the X donor is a chalcogenide donor or a pnictide donor, such as a phosphine chalcogenide, a bis(silyl) chalcogenide, dioxygen, an ammonium salt, or a tris(silyl) pnictide. Suitable X donors include dioxygen, bis(trimethylsilyl) selenide ((TMS)₂Se), trialkyl phosphine selenides such as (tri-n-octylphosphine) selenide (TOPSe) or (tri-n-butylphosphine) selenide (TBPSe), trialkyl phosphine tellurides such as (tri-n-octylphosphine) telluride (TOPTe) or hexapropylphosphorustriamide telluride (HPPTTe), bis(trimethylsilyl)telluride ((TMS)₂Te), bis(trimethylsilyl)sulfide ((TMS)₂S), a trialkyl phosphine sulfide such as (tri-n-octylphosphine) sulfide (TOPS), an ammonium salt such as an ammonium halide (e.g., NH₄Cl), tris(trimethylsilyl) phosphide ((TMS)₃P), tris(trimethylsilyl) arsenide ((TMS)₃As), or tris(trimethylsilyl) antimonide ((TMS)₃Sb). In certain embodiments, the M donor and the X donor can be moieties within the same molecule.

A coordinating solvent can help control the growth of the nanocrystal. The coordinating solvent is a compound having a donor lone pair that, for example, has a lone electron pair available to coordinate to a surface of the growing nanocrystal. Solvent coordination can stabilize the growing nanocrystal. Typical coordinating solvents include alkyl phosphines, alkyl phosphine oxides, alkyl phosphonic acids, or alkyl phosphinic acids, however, other coordinating solvents, such as pyridines, furans, and amines may also be suitable for the nanocrystal production. Examples of suitable coordinating solvents include pyridine, tri-n-octyl phosphine (TOP), tri-n-octyl phosphine oxide (TOPO) and tris-hydroxylpropylphosphine (tHPP). Technical grade TOPO can be used.

Size distribution during the growth stage of the reaction can be estimated by monitoring the absorption line widths of the particles. Modification of the reaction temperature in response to changes in the absorption spectrum of the particles allows the maintenance of a sharp particle size distribution during growth. Reactants can be added to the nucleation solution during crystal growth to grow larger crystals. By stopping growth at a particular nanocrystal average diameter and choosing the proper composition of the semiconducting material, the emission spectra of the nanocrystals can be tuned continuously over the wavelength range of 300 nm to 5 microns, or from 400 nm to 800 nm for CdSe and CdTe. The nanocrystal has a diameter of less than 150 Å. A population of nanocrystals has average diameters in the range of 15 Å to 125 Å.

The nanocrystal can be a member of a population of nanocrystals having a narrow size distribution. The nanocrystal can be a sphere, rod, disk, or other shape. The nanocrystal can include a core of a semiconductor material. The nanocrystal can include a core having the formula MX, where M is cadmium, zinc, magnesium, mercury, aluminum, gallium, indium, thallium, or mixtures thereof, and X is oxygen, sulfur, selenium, tellurium, nitrogen, phosphorus, arsenic, antimony, or mixtures thereof.

The core can have an overcoating on a surface of the core. The overcoating can be a semiconductor material having a composition different from the composition of the core. The overcoat of a semiconductor material on a surface of the nanocrystal can include a

Group II-VI compound, a Group II-V compound, a Group III-VI compound, a Group III-V compound, a Group IV-VI compound, a Group I-III-VI compound, a Group II-IV-VI compound, and a Group II-IV-V compound, for example, ZnO, ZnS, ZnSe, ZnTe, CdO, CdS, CdSe, CdTe, MgO, MgS, MgSe, MgTe, HgO, HgS, HgSe, HgTe, AN, AlP, AlAs, AlSb, GaN, GaP, GaAs, GaSb, InN, InP, InAs, InSb, TlN, TlP, TlAs, TlSb, TlSb, PbS, PbSe, PbTe, or mixtures thereof. For example, ZnS, ZnSe or CdS overcoatings can be grown on CdSe or CdTe nanocrystals. An overcoating process is described, for example, in U.S. Pat. No. 6,322,901. By adjusting the temperature of the reaction mixture during overcoating and monitoring the absorption spectrum of the core, over coated materials having high emission quantum efficiencies and narrow size distributions can be obtained. The overcoating can be between 1 and 10 monolayers thick.

The particle size distribution can be further refined by size selective precipitation with a poor solvent for the nanocrystals, such as methanol/butanol as described in U.S. Pat. No. 6,322,901. For example, nanocrystals can be dispersed in a solution of 10% butanol in hexane. Methanol can be added dropwise to this stiffing solution until opalescence persists. Separation of supernatant and flocculate by centrifugation produces a precipitate enriched with the largest crystallites in the sample. This procedure can be repeated until no further sharpening of the optical absorption spectrum is noted. Size-selective precipitation can be carried out in a variety of solvent/nonsolvent pairs, including pyridine/hexane and chloroform/methanol. The size-selected nanocrystal population can have no more than a 15% rms deviation from mean diameter, preferably 10% rms deviation or less, and more preferably 5% rms deviation or less.

The outer surface of the nanocrystal can include compounds derived from the coordinating solvent used during the growth process. The surface can be modified by repeated exposure to an excess of a competing coordinating group. For example, a dispersion of the capped nanocrystal can be treated with a coordinating organic compound, such as pyridine, to produce crystallites which disperse readily in pyridine, methanol, and aromatics but no longer disperse in aliphatic solvents. Such a surface exchange process can be carried out with any compound capable of coordinating to or bonding with the outer surface of the nanocrystal, including, for example, phosphines, thiols, amines and phosphates. The nanocrystal can be exposed to short chain polymers which exhibit an affinity for the surface and which terminate in a moiety having an affinity for a suspension or dispersion medium. Such affinity improves the stability of the suspension and discourages flocculation of the nanocrystal. Nanocrystal coordinating compounds are described, for example, in U.S. Pat. No. 6,251,303, which is incorporated by reference in its entirety.

For example, the outer surface of the nanocrystal can include a polyacrylate moiety that has multiple negative charges when in aqueous solution. See, for example, WO/2007/021757, which is incorporated by reference in its entirety.

Thin films having a high oscillator strength (i.e., absorption coefficient) can be made by alternately adsorbing two or more materials capable of non-covalent interaction onto a support or substrate from solution, where one material is a light absorbing material. The non-covalent interaction can be, for example, an electrostatic interaction or hydrogen bonding. Selection of appropriate materials and assembly conditions can result in a film where the light absorbing material participates in strong dipole-dipole interactions, favoring a high absorption coefficient. The light absorbing material can be a dye capable of forming a J-aggregate. See, for example, WO/2007/018570, which is incorporated by reference in its entirety. Such films can also be included in light emitting devices. See, for example, WO/2006/137924, which is incorporated by reference in its entirety.

Layers of light absorbing material, which can be positively or negatively charged, can be interspersed with layers of an oppositely charged material. The oppositely charged material can include a multiply charged species. A multiply charged species can have a plurality of charge sites each bearing a partial, single, or multiple charge; or a single charge site bearing a multiple charge. A polyelectrolyte, for example, can have a plurality of charge sites each bearing a partial, single, or multiple charge. A polyelectrolyte has a backbone with a plurality of charged functional groups attached to the backbone. A polyelectrolyte can be polycationic or polyanionic. A polycation has a backbone with a plurality of positively charged functional groups attached to the backbone, for example poly(allylamine hydrochloride). A polyanion has a backbone with a plurality of negatively charged functional groups attached to the backbone, such as sulfonated polystyrene (SPS), polyacrylic acid, or a salt thereof. Some polyelectrolytes can lose their charge (i.e., become electrically neutral) depending on conditions such as pH. Some polyelectrolytes, such as copolymers, can include both polycationic segments and polyanionic segments. The charge density of a polyelectrolyte in aqueous solution can be pH insensitive (i.e., a strong polyelectrolyte) or pH sensitive (i.e., a weak polyelectrolyte). Without limitation, some exemplary polyelectrolytes are poly diallyldimethylammonium chloride (PDAC, a strong polycation), poly allylamine hydrochloride (PAH, a weak polycation), sulfonated polystyrene (SPS, a strong polyanion), and poly acrylic acid (PAA, a weak polyanion). Examples of a single charge site bearing a multiple charge include multiply charged metal ions, such as, without limitation, Mg²⁺, Ca²⁺, Zn²⁺, Fe²⁺, Fe³⁺, Co²⁺, Cu²⁺, Cd²⁺, Sn⁴⁺, Eu³⁺, Tb³⁺, and the like. Multiply charged metal ions are available as salts, e.g. chloride salts such as CoCl₂, FeCl₃, EuCl₃, TbCl₃, CdCl₂, and SnCl₄.

The film can include hydrogen bonding polymers, such as, for example, polyacrylamide (PAm), polyvinylpyrolidone (PVP), and polyvinyl alcohol (PVA). The light absorbing film can include more than two materials. One of these materials is the light absorbing material and one of the other materials is either a multivalent ionic species or hydrogen bonding polymer. Additional materials may be included in the film to promote crosslinking, adhesion, or to sensitize light emission or absorption.

The thin films can include one or several layers of a polyelectrolyte and one or more charged species with strong dipole-dipole interactions and any additional dopants. At least one of the charged species used for strong dipole-dipole interactions has a charge opposite that of the polyelectrolyte used for the scaffold. When sequentially applied to a substrate, the oppositely charged materials attract forming an electrostatic bilayer. The polyelectrolyte provides a scaffold for the species with strong dipole-dipole interactions to form a layered structure. These films are compatible with other processes of building thin films through alternate adsorption of charged species. The films can be interspersed in a multifilm heterostructure with other thin films.

The charged species with strong dipole-dipole interactions can be a single type of species, such as a single type of J-aggregating material (for example, a cyanine dye). Alternatively, several charged species with strong dipole-dipole interactions among the species could be used. The species used for the strong dipole-dipole interacting layer can have individual dipoles that can couple together to produce a coherent quantum mechanical state. This allows for the buildup of coherence in two dimensions, producing effects in the probe dimension perpendicular to the interacting species. The excitation phenomena has been well-documented by a Frenkel excitation model, in which the characterization of J-aggregates have been attributed to coupling between chromophore transition dipoles and the consequent delocalization of excitation energy in the aggregate. See, for example, Davydov, A. S. Theory of Molecular Excitons; Plenum Press, 1971; van Burgel, M et al., Chem. Phys. 1995, 102, 20-33; Mishra, A et al., Chem. Rev. 2000, 100,1973-2011; Knoester, J. Optical Properties of Molecular Aggregates. Proceedings of the International School of Physics “Enrico Fermi”, 2002; Knoester, J. Int. J. Photoenergy 2006, 61364, 1-10; Lebedenko, A. N.; et al., J. Phys. Chem. C 2009, 113, 12883-12887, each of which is incorporated by reference in its entirety. The spectrally narrow, intense absorption of J-aggregates led to their widespread use, for example, in photographic film, where light absorption by the dye aggregates is followed by reduction of silver halide particles. See, for example, J-aggregates; Kobayashi, T., Ed.; World Scientific, Singapore, 1996, which is incorporated by reference in its entirety.

The J-aggregation effect is made possible by the flat, elongated morphology of the cyanine dye, which controls packing, and the presence of a strong dipole formed from a conjugated pi system that forms the backbone of the molecule. The dye 1,1′,3,3′-tetraethyl-5,5′,6,6′-tetrachlorobenzimidazolo-carbocyanine chloride (TTBC) has been proposed to occur in a “herringbone” or “staircase” type arrangement. See, e.g., Birkan, B.; Gulen, D.; Ozcelik, S. Journal of Physical Chemistry B 2006, 110, 10805-10813, which is incorporated by reference in its entirety. When the dye monomers are positioned and aligned such that their optical transition dipoles couple strongly and constructively, the aggregates form the collectively emitting J-band state, whose signature photoluminescence (PL) spectrum is red-shifted and considerably narrower than the PL of the monomer. See, for example, Vanburgel, M.; Wiersma, D. A.; Duppen, K. Journal of Chemical Physics 1995, 102, 20-33; and Knoester, J. Journal of Chemical Physics 1993, 99, 8466-8479, each of which is incorporated by reference in its entirety.

These cyanine dyes often occur as organic salts (Mishra, A.; et al., Chem. Rev. 2000, 100, 1973-2011, which is incorporated by reference in its entirety). Typically, the lumophore component is positively charged due to the partial positive charge on the amine moieties that are coupled to the conjugated pi system that forms the color center of the molecule. The lumophore may instead be negatively charged overall. The resulting J-aggregates are nanoscale charged species generally dispersible in a number of polar solvents, including water and alcohols. Solvent choices can be limited by the conditions required to promote aggregation. These ionic species have been previously shown to adsorb readily onto a charged surface (Fukumoto, Y. Yonezawa, Thin Solid Films 1998, 329; and Bradley, M. S. et al., Advanced Materials 2005, 17, 1881) to AgBr nanocrystalline grains (Rubtsov, I. V.; et al., J. Phys. Chem. A 2002, 106, 2795-2802), and to charged Au nanocrystals in solution (Lim, I.-I. S.; et al., J. Phys. Chem. B 2006, 110, 6673-6682) (each of which is incorporated by reference in its entirety). They have also been shown to be efficient FRET acceptors and donors when assembled above a film of layer-by-layer deposited polyelectrolyte-CdSe/ZnS nanocrystal monolayers (Zhang, Q.; et al., Nat Nano 2007, 2, 555-559, which is incorporated by reference in its entirety). Electrostatic synthesis of complex compounds involving nanocrystals has also been demonstrated using dihydrolipoic acid (DHLA) coated, negatively charged nanocrystals and positively charged polypeptides such as a leucine zipper (see, for example, Mattoussi, H.; et al., J. Am. Chem. Soc. 2000, 122, 12142-12150, which is incorporated by reference in its entirety).

J-aggregates of cyanine dyes have long been known for their strong fluorescence. This strong fluorescence makes J-aggregates a desirable candidate for use in organic light-emitting devices (OLEDs), and these devices have been demonstrated. The layer-by-layer (LBL) technique for film growth, first developed by Decher et al., was extended to create thin films of J-aggregates, which have been to create an OLED with J-aggregates as emitters.

See, for example, E. E. Jelley, Nature 1936, 138, 1009; M. Era, C. Adachi, T. Tsutsui, S. Saito, Chem. Phys. Lett. 1991, 178, 488; G. Decher, J. D. Hong, J. Schmitt, Thin Solid Films 1992, 210, 831; H. Fukumoto, Y. Yonezawa, Thin Solid Films 1998, 329, 748; S. Bourbon, M. Y. Gao, S. Kirstein,Synthetic Metals 1999, 101, 152; Bradley, M.S. et al., Advanced Materials 2005, 17, 1881; and provisional U.S. Patent Application No. 60/624,187, filed Nov. 3, 2004, each of which is incorporated by reference in its entirety.

J-aggregates can also act as photosensitizers through excitation energy transfer (EET). See, for example, Spitz, C. et al., Int. J. Photoenergy 2006, 84950, 1-7, and Scheibe, G., et al., Naturwissenschaften 1939, 27, 499-501, each of which is incorporated in its entirety. Semiconductor nanocrystals and J-aggregates in solution can demonstrate efficient EET from J-aggregates to conjugated semiconductor nanocrystals, resulting in enhanced light absorption and increased photoluminescence at the semiconductor nanocrystal wavelength. See, for example, Walker, B. J., et al., J. Am. Chem. Soc. 2009, 131, 9624-9625, which is incorporated by reference in its entirety. By incorporating semiconductor nanocrystals within the J-aggregate matrix, the light harvesting and light emitting processes can be distributed between materials that are optimized for each role. The close conjugation of semiconductor nanocrystals and coherently-coupled dyes can aid in photoluminescence downconversion beyond the levels already achieved through field enhancements, changes in semiconductor nanocrystal chemistry, device architecture, or matrix dispersion conditions, and energy transfer can be used to enhance light harvesting in heterostructured devices. See, for example, Lee, J. et al., Adv. Mater. 2000, 12, 1102-1105; Chen, Y., et al., Appl. Phys. Lett. 2008, 93, 053106; Millstone, J. E., et al., Small 2009, 5, 646-664; Fofang, N. T., et al., Nano Lett. 2008, 8, 3481-3487; Steckel, J. S., et al., Angew. Chem. Int. Ed. 2006, 45, 5796-5799; Wood, V., et al., Adv. Mater. 2009, 21, 2151-2155; Kwak, J., et al., Adv. Mater. 2009, 21, 5022-5026. Rogach, A. L., et al., Mater. Chem. 2009, 19, 1208-1221; Yum, J. H., et al., Angew. Chem. Int. Ed. 2009, 48, 9277-9280; Anikeeva, P. O., et al., Chem. Phys. Lett. 2006, 424, 120-125; Taylor, R. M., et al., Displays 2007, 28, 92-96; Anikeeva, P. O., et al., Phys. Rev. B, 2008, 78, 085434, each of which is incorporated by reference in its entirety.

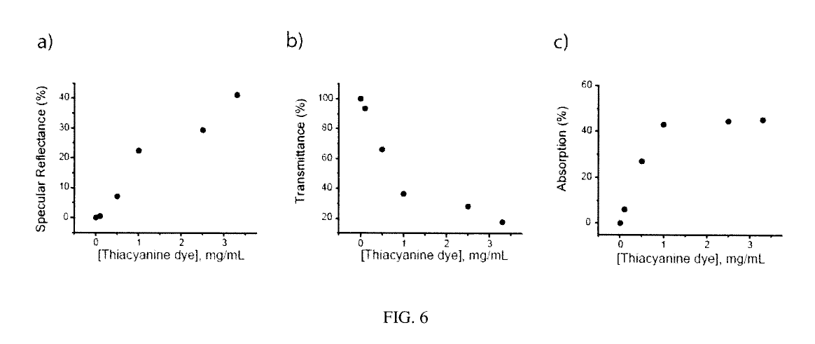

Because a film of J-aggregated thiacyanine dyes (TC) that is 13 nm thick can absorb 40\% of the incident light at 465 nm, its light attenuation length can be 3.3× less than a film of CdS and 4× less than the unaggregated dye. FIG. 6 shows the scatter graphs for (a) reflectance; (b) transmittance; and (c) absorption coefficients measured at the TC J-aggregate maximum (˜465 nm) for deposition solutions with a range of TC concentration. See, for example, Hu, K.; Brust, M.; Bard, A. J. Chem. Mater. 1998, 10, 1160-1165, which is incorporated by reference in its entirety. Efficient energy transfer from J-aggregates to associated semiconductor nanocrystals can result in increased light harvesting and enhanced photoluminescence relative to a film with the same quantity of semiconductor nanocrystals alone. The molecular excitons in J-aggregates can be analogous to the physics of biological light harvesting systems, and blended semiconductor nanocrystal/J-aggregate films may be interesting model systems for fundamental studies of light-matter interactions. See, for example, Knoester, J. Int. J. Photoenergy 2006, 61364, 1-10; van Amerongen, H., et al., Photosynthetic Excitons; World Scientific, Singapore, 2000; Kim, O. K., et al., Org. Lett. 2008, 10, 1625-1628; Calzaferri, G., et al., Photochem. Photobiol. Sci. 2008, 7, 879-910; Kirstein, S., et al., Int. J. Photoenergy 2006, 20363, 1-21, each of which is incorporated by reference in its entirety.

Like most J-aggregates, aggregation of TC in films can depend on dye concentration and polarity of the deposition solvent(s), and conditions that lead to a high degree of J-aggregation are often incompatible with semiconductor nanocrystals or with solution processing. See, for example, Mishra, A., et al., P. Chem. Rev. 2000, 100, 1973-2011, which is incorporated by reference in its entirety. Previously, the low volatility and poor wetting of the conjugations aqueous solutions made them less desirable than organic solvents for NC/J-aggregate deposition.

### EXAMPLES

Chemicals.

All reagents were used without additional purification unless noted. Thiacyanine dye (NK 3989) was obtained from Charkit Chemical Corp.; 2,2,2-triuoroethanol (TFE) and Girard's Reagent T [CAS 123-46-6] were obtained from Sigma Aldrich. 1-butanol, methanol, acetone, and isopropanol were all OmniSolv brand purchased from VWR. Micro-90 detergent was also purchased from VWR. Quartz slides (2.5 cm×2.5 cm) were purchased from Chemglass.

Nanocrystal synthesis.

ZnSe/CdSe/ZnS nanocrystals were synthesized using known methods. For example, see Walker, B. J., et al. J. Am. Chem. Soc. 131, 9624-9625 (2009), which is incorporated by reference in its entirety.

Ligand Exchange of CdSe(ZnCdS) with TFE.

A solution of semiconductor nanocrystal growth solution (8 mL, 2.5 μmol/L) was flocculated via addition of n-butanol and methanol, followed by centrifugation at 3900 rpm. After evaporation of residual solvents in air from the separated semiconductor nanocrystal solids, 2 mL of a 2-mercaptoethyl-(N,N,N-trimethylammonium) chloride solution (65 mg/mL) was added directly to the centrifuge tube. The semiconductor nanocrystals were immediately resuspended in the solution at 23° C. ambient temperature, with minimum stiffing required. Excess ligands were removed as follows. The semiconductor nanocrystals were precipitated two additional times by adding H₂O (˜2 mL) until turbid, then centrifuged to separate the water soluble-mta ligands from the flocculated semiconductor nanocrystals. TFE (2 mL) was added to resuspend the semiconductor nanocrystals. After the final resuspension, the semiconductor nanocrystals were centrifuged at 5000 rpm and filtered (200 nm Acrodisc PTFE syringe filter) to remove large particulates. The photoluminescence quantum yield of these semiconductor nanocrystals in TFE was 60\%.

CdSe(ZnS) semiconductor nanocrystals become dispersable in alcohol via ligand exchange with amines that contain polar functional groups. See, for example, Chan, Y., et al., Adv. Mater. 16, 2092-2097 (2004), which is incorporated by reference in its entirety. For additional material versatility, cationic surface charge can be imparted to CdSe(ZnS) semiconductor nanocrystals via a ligand exchange similar to that described above, using Girard's Reagent T rather than mta. The photoluminescence QY of these species in solution was 57%.

Measurement and other characterization.

A Cary 5000 Spectrophotometer was used in double-beam mode for all thin film transmittance measurements. For absolute reflectance measurements, the Cary was fitted with a 45° C. specular reflectance attachment and both of the two incident beams had matching plane polarizations. Photoluminescence and photoluminescence excitation measurements were taken using a Fluoromax-3 Fluorimeter. All thin film photoluminescence quantum yield measurements were taken using an integrating sphere. Fluorescence micrographs were obtained using a Nikon Eclipse ME600 epifluorescence optical microscope fitted with a Nikon DXM1200 digital camera. All other qualitative images were taken using a Canon Powershot G9 digital camera.

Surface characterization was performed using a Veeco/Digital Instruments Dimension D3100s-1 atomic force microscope (AFM). Transmission electron micrographs were taken with a JEOL 200CX TEM operating at 120 kV. Focused ion beam tomography was carried out using a JEOL JEM-9310 Focused Ion Beam system.

All film thicknesses were determined by scratching the film or by lifting off a corner of the film with tape, then analyzing the height difference via AFM. AFM data was processed using WS×M. See, for example, Horcas, I., et al., A. M. Rev. Sci. Instrum. 78, 013705 (2007), which is incorporated by reference in its entirety.

Blended Film Deposition of Nanocrystal/J-aggregate Constructs.

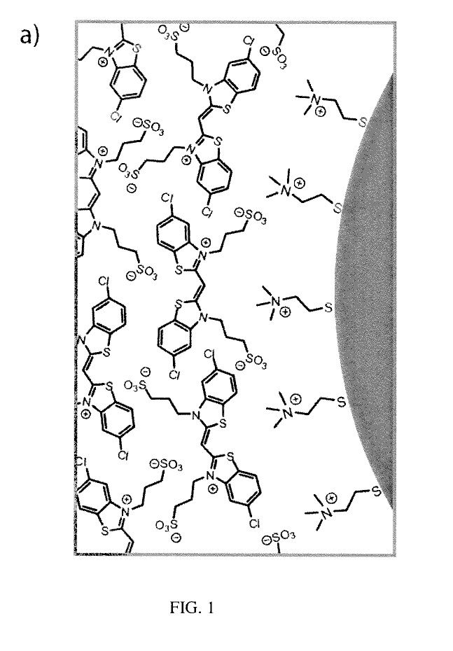

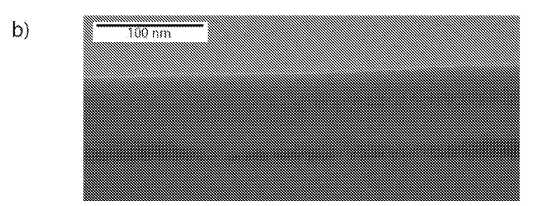

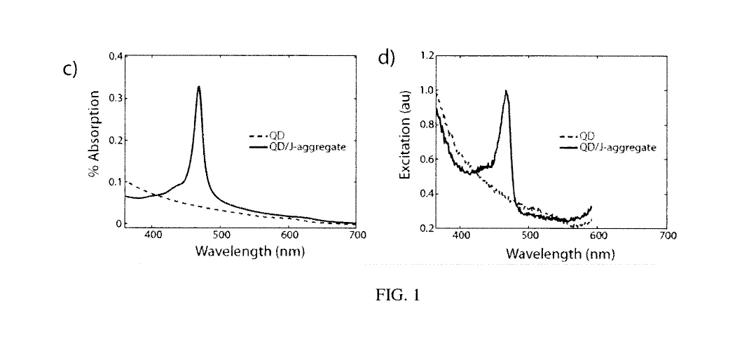

NC/J-aggregate constructs were deposited in blended films as follows. After a ligand exchange using 2-mercaptoethyl-(N,N,N-trimethylammonium) chloride (mta), ZnCdS(CdSe) semiconductor nanocrystals were suspended in 2,2,2-trifluoroethanol (TFE) and further purified by repeated precipitation. FIG. 1A shows a schematic of the electronic conjugation of the thiacyanine J-aggregates at the surface of a semiconductor nanocrystal after ligand exchange with 2-mercaptoethyl-(N,N,N-trimethylammonium) chloride. To 1 mL of the above semiconductor nanocrystal solution, a solution of TC in TFE (1 mL, 0.3 mg/mL in TC dye) was added. The quartz substrates were cleaned via a sequential washing procedure. See, for example, Bradley, M. S., et al., Adv. Mat. 17, 1881-1886 (2005), which is incorporated by reference in its entirety. After washing the slide with a detergent solution of Micro-90 and rinsing with distilled water, the slide was rinsed sequentially using acetone and isopropanol. The solvent was then evaporated in a vertical orientation and used for further spin coating as follows. 20 mL of the combined NC/TC solution was dropped onto the center of the cleaned slide, which was immediately accelerated to 2000 RPM on a spin coater chuck. After 1 minute, the sample was removed, and the solvent was allowed to evaporate for 1 h before further characterization.

Control films were prepared in an analogous manner, with identical concentrations in either J-aggregates or semiconductor nanocrystals as appropriate. The photoluminescence QY of CdSe(ZnCdS) semiconductor nanocrystals after deposition in thin film was 40\%.

Prior to spin coating, the TC dye is in its non-aggregated form, and it is evident that the spin casting process aids in the formation of TC J-aggregates. See, for example, Tani, K., et al., J. Phys. Chem. B 2008, 112, 836-844, which is incorporated by reference in its entirety. Additionally, the alcohol-based mta ligand exchange results in a somewhat modest drop in photoluminescence quantum yield (a 15\% decrease), compared to the 30-50\% decrease in QY associated with ligand exchange reactions in aqueous conditions. See, for example, Liu,W., et al.,. J. Am. Chem. Soc. 2010, 132, 472-483 and Uyeda, H. T., et al., J. Am. Chem. Soc. 2005, 127, 3870-3878, each of which is incorporated by reference in its entirety. Cross sectional TEM demonstrates the formation of a uniform thin film. FIG. 1B shows the transition electron micrograph of a semiconductor nanocrystal (NC)/J-aggregate heterojunction in cross section wherein the thin film is supported below by a quartz substrate and encased above by graphite/gold deposited via focused ion beam.

The NC/J-aggregate film has the absorption spectrum in FIG. 1C, and the semiconductor nanocrystal absorption spectrum is shown for comparison. As in solution, the absorption spectrum of the NC/J-aggregate thin film has both a J-aggregate absorption feature at 465 nm and the spectral characteristics of semiconductor nanocrystals. See, for example, Walker, B. J., et al., J. Am. Chem. Soc. 2009, 131, 9624-9625, which is incorporated by reference in its entirety. The absorbance of the two films at the lowest excitonic semiconductor nanocrystals feature are comparable, indicating that quantity of semiconductor nanocrystal material is approximately equal in both films.

The excitation spectrum of the NC/J-aggregate film, monitored at 630 nm emission, demonstrates a 2.5-fold enhancement over a film with the same effective thickness of deposited semiconductor nanocrystals. FIG. 1D shows the photoluminescence excitation spectra of semiconductor nanocrystals and NC/J-aggregate films collected at the peak semiconductor nanocrystal emission (620 nm). Thus, for a light source of a given intensity tuned near the J-aggregate absorption maximum at 465 nm (e.g. a InGaN LED), a thin film of NC/J-aggregates results in greater blue light attenuation and a luminescence equivalent to a film of semiconductor nanocrystals that has 2.5× as much material. It is unlikely that the higher fluorescence in the NC/J-aggregate film results solely from dispersing the semiconductor nanocrystals (i.e. from a decrease in self-quenching among semiconductor nanocrystals), as the semiconductor nanocrystal and NC/J-aggregate films have similar emission intensities far from the 465 nm feature.

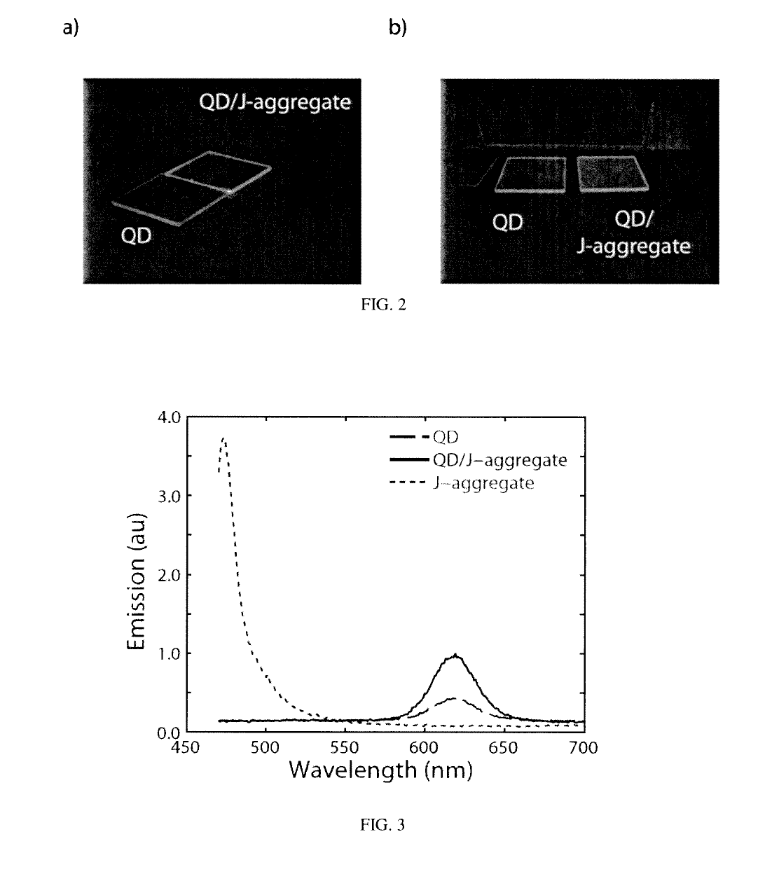

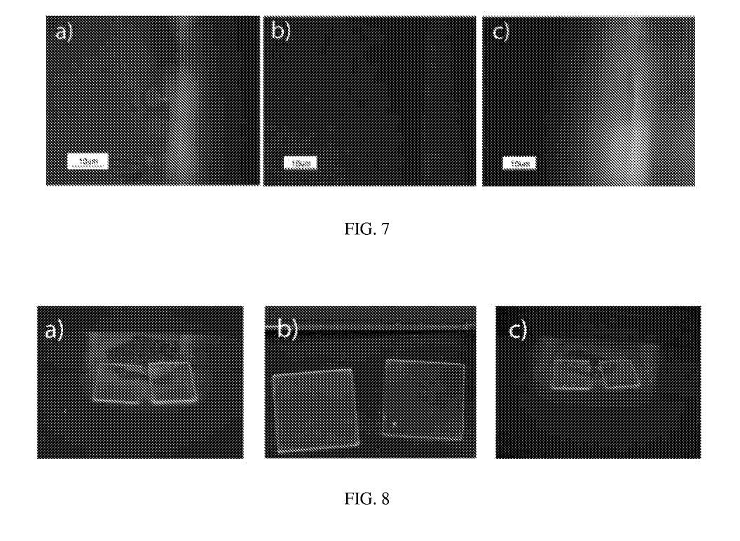

FIG. 2 shows photographs of semiconductor nanocrystal and NC/J-aggregate thin films, taken with a 630 nm band pass filter to remove excitation light wherein (A) films were excited using columated 457 nm illumination at the intersection of the two films and (B) films were excited using broadband UV source centered at 360 nm. The enhanced emission of NC/J-aggregates is qualitatively apparent using the waveguiding characteristic of the substrate. The NC/J-aggregate film demonstrates a clear brightness enhancement relative to the nanocrystal film in a photograph taken using 457 nm excitation (FIG. 2A). No such enhancement was observed for illumination far from the J-aggregate absorption maximum (FIG. 2B). Fluorescence micrographs of the films from an inverted optical microscope showed similar energy transfer and enhancement of the semiconductor nanocrystal emission without the use of a band pass filter. FIG. 7 shows fluorescence micrographs of thin films excited at 465 nm where emission has been waveguided to the edge of the film for (A) NC/J-aggregates; (B) semiconductor nanocrystals; and (C) J-aggregates. An inverted fluorescence microscope was used as an alternative means to image energy transfer and absorption enhancement in NC/J-aggregate blended films (FIG. 7). The fluorescence signals were maximized by imaging the edge of the film, thus taking advantage of waveguiding quartz substrate. The thin semiconductor nanocrystal layer yields little photoluminescence when excited near the J-band maximum, and the J-aggregate control_lm exhibits strong blue-green emission. This J-aggregate emission is quenched in the NC/J-aggregate film, which also shows the enhanced emission indicative of energy transfer. The qualitative results from both experiments are consistent with the PLE spectra in FIG. 1c and with narrowband absorption enhancement via EET.

FIG. 3 shows the photoluminescence spectra taken at 455 nm excitation of the semiconductor nanocrystal, J-aggregate, and NC/J-aggregate films are also consistent with excitation energy transfer. Upon illumination at 457 nm, the semiconductor nanocrystal film emits at 620 nm and the J-aggregate film emits at 472 nm. In the NC/J-aggregate film, where the J-aggregate donors are blended with semiconductor nanocrystal acceptors, the 620 nm emission is enhanced and the 472 nm emission is quenched. The acceptor emission enhancement is consistent to within 10% of the PLE spectra, and the extent of donor quenching corresponds to a EET efficiency of ˜90%. Although the donor quenching ratio appears to be greater than 99% in these spectra, repeated measurements revealed a distribution of quenching ratios that may result from the orientation-dependence of the measurement.

This EET efficiency exceeds that reported in a previous experiment, likely because the donors and acceptors in the previous work were separated by alternating layers of a polyelectrolyte and because TC J-aggregates have a better spectral overlap with semiconductor nanocrystal acceptors than the J-aggregates used previously. See, for example, Zhang, Q., et al., Nat. Nanotechnol 2007, 2, 555-559, which is incorporated by reference in its entirety. The high EET efficiency in the present work approaches the EET efficiencies previously reported in solution using identical quantum dots, charged surface ligands, and J-aggregates. See, for example, Walker, B. J., et al., J. Am. Chem. Soc. 2009, 131, 9624-9625, which is incorporated by reference in its entirety.

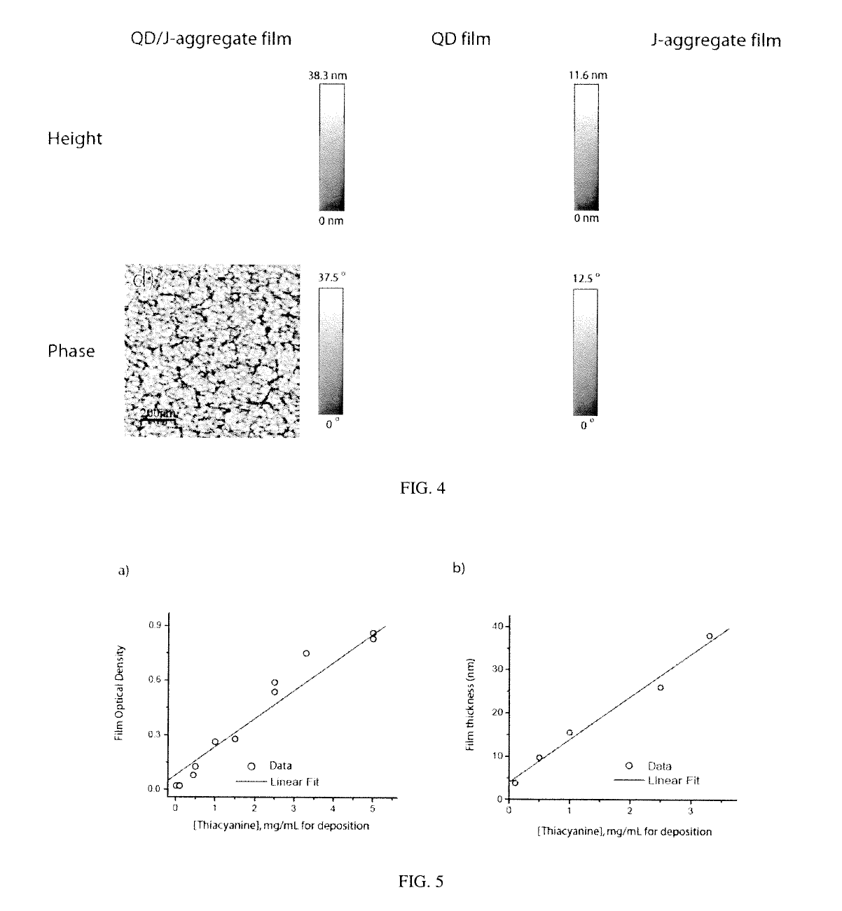

FIG. 4 shows tapping-mode atomic force micrographs for height (a, b, c) and phase (d, e, f) of NC/J-aggregates, semiconductor nanocrystals, and J-aggregates wherein the RMS roughness of the films were 6.43 nm, 1.46 nm, and 0.8 nm, respectively. The morphology of the NC/J-aggregate thin films were characterized using atomic force microscopy (FIG. 4A), with the semiconductor nanocrystal and J-aggregate films shown for comparison (FIG. 4B-C). Unlike either of the constituent films, the NC/J-aggregate film has less spatial continuity than either of the constituent films, and it consists of mounded structures that may arise from disordered semiconductor nanocrystal intercalation into the long-range structure of J-aggregates. The phase contrast image of the NC/J-aggregate film (FIG. 4D) is substantially different from the phase contrast of either the semiconductor nanocrystal or the J-aggregate, (FIG. 4E-F) indicating that the surface interactions of the NC/J-aggregate also differ from either constituent. See, for example, Tamayo, J., et al., Langmuir 1996, 12, 4430-4435, which is incorporated by reference in its entirety. The spacing between adjacent surface peaks ˜50 nm) is also consistent with the length scales measured for exciton delocalization of other J-aggregates in the solid state, and the morphology of the NC/J-aggregate blended films is thus consistent with efficient excitation energy transfer. See, for example, Higgins, D. A., et al., J. Phys. Chem. 1995, 99; Lin, H., et al., Nano Lett. 2010, 10, 620-626, each of which is incorporated in its entirety.

Like many organic fluorophores, J-aggregates are susceptible to photo-oxidation when exposed to light under ambient conditions. To assess the degradation of TC J-aggregate donors in the solid state, the brightness of J-aggregate films were evaluated qualitatively before and after continuous excitation at 360 nm. Although a sample film grew dim after 1 h excitation in air, an identical sample that was excited in an inert atmosphere largely retained its quantum yield even after 48 h of continuous exposure. Thus, it appears that the J-aggregate energy transfer donors can maintain their photostability for an extended period if protected from an oxidizing environment.

The method described herein is of depositing NC/J-aggregate blended thin films via spin casting. The heterojunction films exhibit 2.5-fold excitation enhancement over a film with the same quantity of semiconductor nanocrystals when excited at 465 nm. NC/J-aggregate films also demonstrate high energy transfer efficiencies. The self-assembly and optical interaction of NC/J-aggregates suggests that these heterostructures may be interesting model systems for studies of light harvesting, and the overlap of the J-aggregate absorption with the emission of common InGaN devices may make these NC/J-aggregate films useful for luminescence downconversion applications.

Determining the Attenuation Length o a TC/J-Aggregate Film

The attenuation length of a TC J-aggregate_lm was determined from the transmittance and reflectance data. TC J-aggregates were spun from TFE solutions of varying concentrations onto quartz substrates, which were then measured via optical spectroscopy and AFM. FIG. 5 shows a linear fit to determine the attenuation length of a thiacyanine J-aggregate film where (A) the optical density is at the 465 nm J-aggregate resonance, measured as a function of the J-aggregated thiacyanine dye (TC) concentration in the 2,2,2-trifluoroethane (TFE) spin coating solution and (B) the average film thickness measured as a function of TC concentration in the TFE spin coating solution. The linear fits from the thickness vs. [TC] and O.D. vs. [TC] are

z=(9:9±0:8)(mL nm/mg)[TC]+(4:0±1:5) nm

O.D.=(0:15±0:01)(mL/mg)[TC]+(0:08±0:04).

From the slopes of these two curves we estimate the attenuation length (in O.D.) for a given concentration of thiacyanine dye [TC].

Measurements of Linear Spectral Parameters for TC/J-Aggregate Films

The TC J-aggregate films have a significant reflectance coefficient (FIG. 6A), and it increases with increasing quantity of the deposited dye. Together with the absorption spectra that level of at 40% absorption (FIG. 6B-C), these data indicate that there is a J-aggregate optical density at which the absorption coefficient is far greater than the reflectance coefficient, (approximately O.D.<0.3). Our samples have O.D. that are far from this threshold value for the entire spectrum, so the NC/J-aggregate films reported in this study have a favorable optical density for J-aggregate light absorption and subsequent energy transfer to quantum dots.

Photobleaching Experiments

Photobleaching experiments demonstrated that J-aggregates were sensitive to photo-oxidation. FIG. 8 shows photographs using 360 nm broad band illumination and a long pass filter 485 nm to remove excitation light where the (A) two films were photographed immediately after deposition; (B) left film was stored in ambient air without light exposure and the right film was exposed to ambient air and UV light for 1 h; and (C) left film was stored in inert air without light exposure and the right film was stored in inert air with UV light exposure for 48 h. Immediately after spinning two TC J-aggregate films under identical conditions, the two films have identical photoluminescence in air (FIG. 8A) One of the two films was left underneath a 360 nm UV lamp for 1 h in air, and it demonstrated both a spectral shift and a reduction in brightness relative to a film that was stored in air without light exposure (FIG. 8B).

Another pair of films was transferred immediately to an inert air glove box. One film was exposed to continuously to light at 360 nm, and the other was stored to avoid light. After 48 h, the UV lamp excitation itself had changed in appearance (FIG. 8C) but the emission wavelength and intensity were largely the same as the unexposed control film.

“Brightness” in Measurements of Absorption Enhancement

The connection between brightness and absorption enhancement is not always intuitive, and absorption measurements in particular are more complicated in thin film than in solution. Therefore it is beneficial to consider the meaning of “brightness” in more detail.

Here, the term brightness is considered synonymous with “the number of photons collected.” This has an inherent spectral dependence, as the number of photons collected depends on the spectral range of the detector. Photoluminescence is also a function of the excitation wavelength.

Brightness is quantified by n_{PL}(λ_{1;2}), the number of photons detected at wavelength λ₂ after excitation at a wavelength λ₁. Then

n_{PL}(λ_{1;2})=n_{PK}(λ_{1;2})n_{A}(λ₁) (1)

where n_{LP}(λ_{1;2}) is the photoluminescence quantum yield for emission at wavelength λ₂ after excitation at a wavelength λ₁, and n_{A}(λ₁) is the number of photons absorbed by the measured film area at (λ₁).

n_{A}(λ₁) itself is a product of two factors: the incoming flux of photons Φ(λ₁), which is constant during all replicated experiments, and the absorption coefficient of the film A(λ₁). In summary, n_{A}(λ₁)=Φ(λ₁) A(λ₁).

Determining the absorption coefficient is more complicated in thin films than for homogeneous solutions, due to significant film reflectance. Based on relationships between absorption, reflection and transmission, the absorption coefficient A at wavelength λ₁ is

A(λ₁)=1−10^{-σ(λ1)pl}−R(λ₁) (2)

with absorption cross section σ(λ₁), density of absorbers p, path length l, and reflectance coefficient R(λ₁). The density of absorbers is the number of absorbers χ_{A} in the excitation region of interest divided by volume; this volume contains both an area term Λ and a path length, which cancels with l. Introducing this change, and substituting 2 into 1,

n_{PL}(λ_{1;2})=n_{PL}(λ_{1;2})Φ(λ₁)[1−10^{-σ(λ1)pl}−R(λ₁)] (3)

Now consider the application of this relationship to the current experiment. If the quantum yield of the emitting semiconductor nanocrystals is reasonably constant before and after the addition of the J-aggregates, and if the quantity of semiconductor nanocrystals and their area of coverage is approximately the same, then the only parts of this expression that change significantly during the addition of J-aggregates to the semiconductor nanocrystal film are σ(λ₁) and R(λ₁). As noted above, the reflectance coefficient R increases monotonically over the relevant range of TC J-aggregate film thicknesses, resulting in an upper bound for the absorbance of the thin film. The films described herein are far from this limit however, and after subtracting the contribution from reflectance it is evident that most of the light attenuation is due to absorbance. Thus, σ(λ₁) is the chief experimental variable in the measurement of the number of photons (“brightness”) from a film of semiconductor nanocrystals energy transfer acceptors with and without associated J-aggregate donors.

Other embodiments are within the scope of the following claims.

What is claimed is:

1. A film comprising:
a plurality of semiconductor nanocrystals; and
a J-aggregating material, the plurality of semiconductor nanocrystals and the J-aggregating material being arranged on a surface and to transfer energy.

2. The film of claim 1, wherein the energy transfer efficiency from the J-aggregating material to the plurality of semiconductor nanocrystals is greater than 80%.

3. The film of claim 2, wherein the energy transfer efficiency from the J-aggregating material to the plurality of semiconductor nanocrystals is 90%.

4. The film of claim 1, wherein the plurality of semiconductor nanocrystals include a cationic surface ligand.

5. The film of claim 1, where the photoluminescence of the film is enhanced at least 2.5 times over an equivalent film including the plurality of semiconductor nanocrystals alone when excited at 465 nm.

6. The film of claim 1, wherein illumination of the film at 457 nm results in enhanced emission at 620 nm and quenched emission at 472 nm.

7. A light emitting device comprising:
a film containing a plurality of semiconductor nanocrystal and a J-aggregating material, the plurality of semiconductor nanocrystal and J-aggregating material being arranged on a substrate and to transfer energy.

11. The device of claim 10, wherein the energy transfer efficiency from the J-aggregating material to the plurality of semiconductor nanocrystals is greater than 80%.

12. The device of claim 11, wherein the energy transfer efficiency from the J-aggregating material to the plurality of semiconductor nanocrystals is 90%.

17. The device of claim 10, where the photoluminescence is enhanced at least 2.5 times over an equivalent film including the plurality of semiconductor nanocrystals alone when excited at 465 nm.

18. The device of claim 10, wherein illumination at 457 nm results in enhanced emission at 620 nm and quenched emission at 472 nm.

19. The device of claim 7, wherein the substrate includes glass, plastic, or quartz.

20. A method of making a film comprising:
contacting a solution containing a plurality of semiconductor nanocrystals and a J-aggregating material with a substrate; and
arranging a plurality of semiconductor nanocrystals and a J-aggregating material on the substrate and to transfer energy.

21. The method of claim 20, wherein producing a plurality of semiconductor nanocrystals includes a cationic surface ligand.

22. The method of claim 20, further comprising suspending the plurality of semiconductor nanocrystals in a fluorinated solvent.

23. The method of claim 20, wherein contacting the solution containing the plurality of semiconductor nanocrystals and the J-aggregating material with a substrate includes spin casting.

24. The method of claim 20, wherein the substrate includes glass, plastic, or quartz.
